(19) United States
(12) Patent Application Publication
(10) Pub. No.: US 2025/0111965 A1
(43) Pub. Date: Apr. 3, 2025

(54) RESISTOR MOUNTING STRUCTURE

(71) Applicant: ROHM CO., LTD., Kyoto-shi (JP)

(72) Inventors: Hideo HARA, Kyoto-shi (JP); Masaaki MATSUO, Kyoto-shi (JP)

(21) Appl. No.: 18/981,049

(22) Filed: Dec. 13, 2024

Related U.S. Application Data
(63) Continuation of application No. PCT/JP2023/020024, filed on May 30, 2023.

(30) Foreign Application Priority Data
Jun. 24, 2022 (JP) 2022-102185

(51) Int. Cl. H01C 1/01; H01C 1/14

(52) U.S. Cl. CPC H01C 1/01; H01C 1/14

(57) ABSTRACT

A mounting structure includes: a substrate; a conductive portion (a first conductive portion and a second conductive portion); a resistor arranged on a path through which a current flows in the conductive portion; and a detection wiring portion (a first detection wiring and a second detection wiring) electrically connected to the resistor. The first conductive portion includes a first pad portion arranged on a first side in a first direction. The second conductive portion includes a second pad portion offset from the first pad portion to a second side in the first direction. The mounting structure further includes a first conductive bonding member for bonding a first pad obverse surface and the resistor (the first portion), and a second conductive bonding member for bonding a second pad obverse surface and the resistor (the second portion). A first wiring obverse surface (a second wiring obverse surface) is offset to a second side in a thickness direction relative to the first pad obverse surface (the second pad obverse surface).

### TECHNICAL FIELD

The present disclosure relates to a mounting structure for a resistor.

### BACKGROUND ART

Semiconductor devices incorporating power switching elements, such as metal oxide semiconductor field effect transistors (MOSFETs) and insulated gate bipolar transistors (IGBTs), have been conventionally known. Such semiconductor devices are used in various electronic devices, ranging from industrial devices to home appliances and information terminals, or even to vehicle-mount devices. JP-A-2015-220429 discloses a conventional semiconductor device. The semiconductor device disclosed in JP-A-2015-220429 includes a base (substrate), a conductive plate (conductor), and a semiconductor element. The conductive plate is supported by the base, and forms a conductive path through which a current flows to the semiconductor element. The semiconductor element is supported by the base and electrically connected to the conductive plate.

When the semiconductor device described above is mounted on a circuit board such as a printed circuit board (PCB), a shunt resistor may be separately mounted on the circuit board, so that the shunt resistor can be used as a flow divider to detect a current. However, in regard to the circuit board, it is necessary to separately mount the shunt resistor and route wires for the resistor. As a result, the space occupied for current detection becomes large, and this has been a factor in increasing cost.

### BRIEF DESCRIPTION OF THE DRAWINGS

FIG. 1 shows an example of a schematic configuration of a mounting structural body including a mounting structure for a resistor according to the present disclosure.

FIG. 2 is an enlarged plan view showing a part of the mounting structural body according to a first embodiment of the present disclosure.

FIG. 3 is a cross-sectional view taken along line III-III in FIG. 2.

FIG. 4 is an enlarged plan view showing a part of the mounting structural body according to a first variation of the first embodiment.

FIG. 5 is a cross-sectional view taken along line V-V in FIG. 4.

FIG. 6 is an enlarged plan view showing a part of the mounting structural body according to a second variation of the first embodiment.

FIG. 7 is a cross-sectional view taken along line VII-VII in FIG. 6.

FIG. 8 is an enlarged plan view showing a part of the mounting structural body according to a third variation of the first embodiment.

FIG. 9 is a cross-sectional view taken along line IX-IX in FIG. 8.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

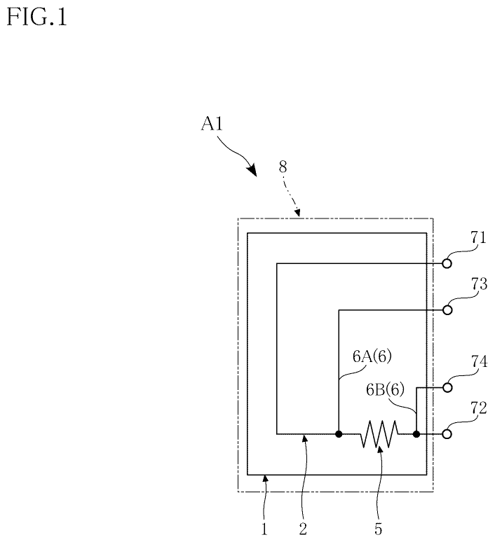

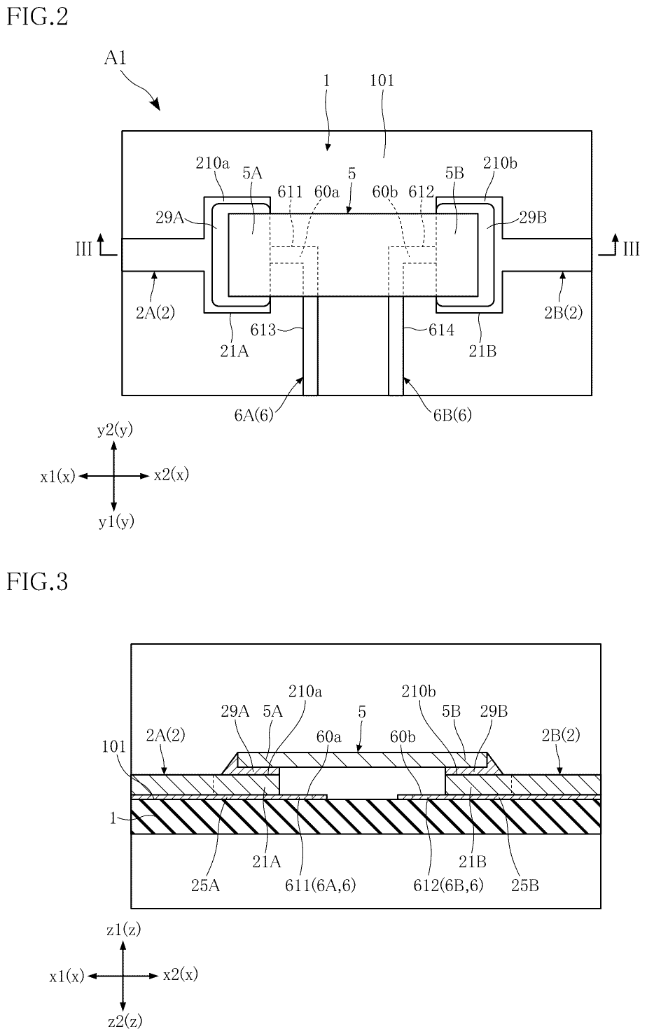

FIGS. 1 to 3 show a mounting structural body including a mounting structure for a resistor according to a first embodiment of the present disclosure. FIG. 1 shows a schematic configuration of a mounting structural body A1. FIG. 2 is an enlarged plan view showing a part of the mounting structural body A1. FIG. 3 is a cross-sectional view taken along line III-III in FIG. 2.

The mounting structural body A1 of the present embodiment includes a substrate 1, a conductive portion 2, a resistor 5, a detection wiring portion 6, terminals 71 and 72, detection terminals 73 and 74, and a sealing resin 8. The mounting structural body A1 is used to detect the current flowing through the conductive portion 2 between the two terminals 71 and 72.

In the description of the mounting structural body A1, the thickness direction (plan-view direction) of the substrate 1 is an example of a “thickness direction” in the present disclosure, and is referred to as a “thickness direction z”. A direction perpendicular to the thickness direction z is an example of a “first direction” in the present disclosure, and is referred to as a “first direction x”. The direction perpendicular to the thickness direction z and the first direction x is an example of a “second direction” in the present disclosure, and is referred to as a “second direction y”. The left side in FIG. 2 is an example of “one side in the first direction” in the present disclosure, and is referred to as an “x1 side in the first direction x”. The right side in FIG. 2 is an example of “the other side in the first direction”, and is referred to as an “x2 side in the first direction x”. The lower side in FIG. 2 is an example of “one side in the second direction” in the present disclosure, and is referred to as a “y1 side in the second direction y”. The upper side in FIG. 2 is an example of “the other side in the second direction” in the present disclosure, and is referred to as a “y2 side in the second direction y”.

The upper side in FIG. 3 is an example of “one side in the thickness direction” in the present disclosure, and is referred to as a “z1 side in the thickness direction z”. The lower side in FIG. 3 is an example of “one side in the thickness direction”, and is referred to as a “z2 side in the thickness direction z”.

The substrate 1 is electrically insulative. The substrate 1 is made of a ceramic material containing alumina (Al₂O₃), for example. It is preferable that the substrate 1 be made of a having a relatively high thermal conductivity. As shown in FIGS. 2 and 3, the substrate 1 has a first obverse surface 101. The first obverse surface 101 faces the z1 side in the thickness direction z.

The conductive portion 2 forms a path through which a current flows. A current targeted for detection flows through the conductive portion 2 between the two terminals 71 and 72. As shown in FIGS. 2 and 3, the conductive portion 2 is supported by the substrate 1. The conductive portion 2 is formed from a lead frame, for example. The lead frame is made of a material containing copper (Cu) or a Cu alloy. In the present embodiment, the conductive portion 2 includes a first conductive portion 2A and a second conductive portion 2B. The first conductive portion 2A and the second conductive portion 2B are disposed on the first obverse surface 101 of the substrate 1. Details of the first conductive portion 2A and the second conductive portion 2B will be described below.

The resistor 5 is a passive element having a function of detecting a current in the mounting structural body A1. The resistor 5 is arranged on the path through which a current flows in the conductive portion 2. Details of the resistor 5 will be described below.

The detection wiring portion 6 is the portion of wiring electrically connected to the resistor 5. The detection wiring portion 6 is connected to the resistor 5 in parallel so as to divide the flow of a current for detection. The detection wiring portion 6 includes a first detection wiring 6A and a second detection wiring 6B. Details of the detection wiring portion 6 (the first detection wiring 6A and the second detection wiring 6B) will be described below.

The terminals 71 and 72 are connected to the conductive portion 2. The terminals 71 and 72 are connected to a device for providing a current to the conductive portion 2.

The detection terminals 73 and 74 are connected to the first detection wiring 6A and the second detection wiring 6B, respectively, and are connected to a voltmeter for measuring a current.

The sealing resin 8 covers at least a portion of each of the substrate 1, the conductive portion 2, and the detection wiring portion 6, and also covers the resistor 5. Each of the terminals 71 and 72 and the detection terminals 73 and 74 for external connection includes a portion exposed from the sealing resin 8. FIGS. 2 and 3 omits the illustration of the sealing resin 8.

As shown in FIGS. 2 and 3, the first conductive portion 2A has a first pad portion 21A. The first pad portion 21A is arranged on the x1 side in the first direction x. The first pad portion 21A has a first pad obverse surface 210a. The first pad obverse surface 210a faces the z1 side in the thickness direction z. The second conductive portion 2B has a second pad portion 21B. The second pad portion 21B is offset to the x2 side in the first direction x relative to the first pad portion 21A. The second pad portion 21B has a second pad obverse surface 210b. The second pad obverse surface 210b faces the z1 side in the thickness direction z.

In the present embodiment, the mounting structural body A1 includes a first bonding layer 25A and a second bonding layer 25B. The first bonding layer 25A is interposed between the first obverse surface 101 and the first pad portion 21A to bond the first obverse surface 101 and the first pad portion 21A. The second bonding layer 25B is interposed between the first obverse surface 101 and the second pad portion 21B to bond the first obverse surface 101 and the second pad portion 21B. The first bonding layer 25A and the second bonding layer 25B are electrically conductive. Each of the first bonding layer 25A and the second bonding layer 25B is made of a material containing silver (Ag), for example, and is calcined silver. The first bonding layer 25A (the second bonding layer 25B) has an area on which the first conductive portion 2A (the second conductive portion 2B) is not disposed, and serves as a wire on the first obverse surface 101.

The resistor 5 is a plate-like member having a predetermined thickness. The resistor 5 has a rectangular shape elongated in the first direction x as viewed in the thickness direction z. The resistor 5 is made of a metal plate, specifically an alloy of nickel (Ni) and chromium (Cr), an alloy of Cu and manganese (Mn), an alloy of Cu and Ni, an alloy of Cu, Mn and tin (Sn), or an alloy of iron (Fe) and Cr. The constituent material of the resistor 5 is not particularly limited to the examples given above as long as the material is a metal plate.

The resistor 5 is formed across the first pad portion 21A and the second pad portion 21B. The resistor 5 has a first portion 5A and a second portion 5B. The first portion 5A and the second portion 5B are located at the respective ends of the resistor 5 in the longitudinal direction thereof (the first direction x). The first portion 5A is located on the x1 side in the first direction x, and overlaps with the first pad portion 21A as viewed in the thickness direction z. The second portion 5B is located on the x2 side in the first direction x, and overlaps with the second pad portion 21B as viewed in the thickness direction z.

The mounting structural body A1 includes a first conductive bonding member 29A and a second conductive bonding member 29B. The resistor 5 is bonded to the first pad portion 21A and the second pad portion 21B via the first conductive bonding member 29A and the second conductive bonding member 29B. The first conductive bonding member 29A is interposed between the first pad obverse surface 210a and the first portion 5A to bond the first pad obverse surface 210a and the first portion 5A. The second conductive bonding member 29B is interposed between the second pad obverse surface 210b and the second portion 5B to bond the second pad obverse surface 210b and the second portion 5B. The first conductive bonding member 29A and the second conductive bonding member 29B are made of solder, for example.

In the present embodiment, the first bonding layer 25A includes the first detection wiring 6A. The first detection wiring 6A has a first wiring obverse surface 60a. The first wiring obverse surface 60a faces the z1 side in the thickness direction z. The first wiring obverse surface 60a is offset to the z2 side in the thickness direction z relative to the first pad obverse surface 210a of the first pad portion 21A.

The first detection wiring 6A has a first extending portion 611 and a third extending portion 613. As shown in FIGS. 2 and 3, the first extending portion 611 extends from the first pad portion 21A to the x2 side in the first direction x as viewed in the thickness direction z. The first extending portion 611 overlaps with the resistor 5 as viewed in the thickness direction z. The third extending portion 613 is connected to the first extending portion 611, and extends to the y1 side in the second direction y. The third extending portion 613 has a portion overlapping with the resistor 5 and a portion not overlapping with the resistor 5, as viewed in the thickness direction z. This configuration allows the first detection wiring 6A (the first extending portion 611) to be electrically connected to the first pad portion 21A. The first detection wiring 6A is electrically connected to the first portion 5A of the resistor 5 via the first pad portion 21A and the first conductive bonding member 29A. The first detection wiring 6A (the third extending portion 613) is also electrically connected to the detection terminal 73 not shown in FIG. 2 or 3 (see FIG. 1).

In the present embodiment, the second bonding layer 25B includes the second detection wiring 6B. The second detection wiring 6B has a second wiring obverse surface 60b. The second wiring obverse surface 60b faces the z1 side in the thickness direction z. The second wiring obverse surface 60b is offset to the z2 side in the thickness direction z relative to the second pad obverse surface 210b of the second pad portion 21B.

The second detection wiring 6B has a second extending portion 612 and a fourth extending portion 614. As shown in FIGS. 2 and 3, the second extending portion 612 extends from the second pad portion 21B to the x1 side in the first direction x as viewed in the thickness direction z. The second extending portion 612 overlaps with the resistor 5 as viewed in the thickness direction z. The fourth extending portion 614 is connected to the second extending portion 612, and extends to the y1 side in the second direction y. The fourth extending portion 614 has a portion overlapping with the resistor 5 and a portion not overlapping with the resistor 5, as viewed in the thickness direction z. This configuration allows the second detection wiring 6B (the second extending portion 612) to be electrically connected to the second pad portion 21B. The second detection wiring 6B is electrically connected to the second portion 5B of the resistor 5 via the second pad portion 21B and the second conductive bonding member 29B. The second detection wiring 6B (the fourth extending portion 614) is also electrically connected to the detection terminal 74 not shown in FIG. 2 or 3 (see FIG. 1).

Next, advantages of the present embodiment will be described.

The mounting structural body A1 includes a substrate 1, a conductive portion 2, a resistor 5, and a detection wiring portion 6. The resistor 5 is arranged on the path through which a current flows in the conductive portion 2. The detection wiring portion 6 is electrically connected to the resistor 5. The mounting structural body A1 can detect the current flowing through the conductive portion 2 by including the resistor 5. The circuit board on which the mounting structural body A1 is mounted does not need to include a separate resistor or route wires for a resistor, which makes it possible to save space.

The conductive portion 2 includes a first conductive portion 2A and a second conductive portion 2B disposed on a first obverse surface 101 of the substrate 1. The first conductive portion 2A has a first pad portion 21A disposed on the x1 side in the first direction x, and the second conductive portion 2B has a second pad portion 21B offset to the x2 side in the first direction x relative to the first pad portion 21A. The resistor 5 has a first portion 5A overlapping with the first pad portion 21A as viewed in the thickness direction z, and a second portion 5B overlapping with the second pad portion 21B as viewed in the thickness direction Z. A first conductive bonding member 29A is interposed between the first pad portion 21A (a first pad obverse surface 210a) and the first portion 5A. The first conductive bonding member 29A bonds the first pad portion 21A (the first pad obverse surface 210a) and the first portion 5A. A second conductive bonding member 29B is interposed between the second pad portion 21B (a second pad obverse surface 210b) and the second portion 5B. The second conductive bonding member 29B bonds the second pad portion 21B (the second pad obverse surface 210b) and the second portion 5B. With this configuration, the resistor 5 can be arranged appropriately on the path through which a current flows in the conductive portion 2.

A first bonding layer 25A, which s electrically conductive, is interposed between the first obverse surface 101 and the first pad portion 21A to bond the first obverse surface 101 and the first pad portion 21A. The first bonding layer 25A includes a first detection wiring 6A. The first detection wiring 6A has a first extending portion 611. The first extending portion 611 extends from the first pad portion 21A to the x2 side in the first direction x as viewed in the thickness direction z. A second bonding layer 25B, which is electrically conductive, is interposed between the first obverse surface 101 and the second pad portion 21B to bond the first obverse surface 101 and the second pad portion 21B. The second bonding layer 25B includes a second detection wiring 6B. The second detection wiring 6B has a second extending portion 612. The second extending portion 612 extends from the second pad portion 21B to the x1 side in the first direction x as viewed in the thickness direction z.

According to the above configuration, a conductive path is formed that extends from the first portion 5A of the resistor 5 to the first extending portion 611 via the first conductive bonding member 29A and the first pad portion 21A. The first detection wiring 6A has a first wiring obverse surface 60a facing the z1 side in the thickness direction z. The first wiring obverse surface 60a is offset to the z2 side in the thickness direction z relative to the first pad obverse surface 210a of the first pad portion 21A. With this configuration, there is a step in the thickness direction z between the end of the first pad portion 21A on the x2 side in the first direction x and the first extending portion 611 (the first detection wiring 6A), as shown in FIG. 3. This prevents the first conductive bonding member 29A made of solder from flowing inappropriately to the x2 side in the first direction x on the first pad portion 21A during the melting and bonding process. A conductive path is also formed on the side of the second portion 5B of the resistor 5. Specifically, the conductive path extends from the second portion 5B to the second extending portion 612 via the second conductive bonding member 29B and the second pad portion 21B. The second detection wiring 6B has a second wiring obverse surface 60b facing the z1 side in the thickness direction z. The second wiring obverse surface 60b is offset to the z2 side in the thickness direction z relative to the second pad obverse surface 210b of the second pad portion 21B. There is a step in the thickness direction z between the end of the second pad portion 21B on the x1 side in the first direction x and the second extending portion 612 (the second detection wiring 6B). This prevents the second conductive bonding member 29B made of solder from flowing inappropriately to the x1 side in the first direction x on the second pad portion 21B during the melting and bonding process. According to such a configuration, the contact point of the first conductive bonding member 29A with the first portion 5A (the resistor 5) on the x2 side in the first direction x can be set based on the position of the end of the first pad portion 21A on the x2 side in the first direction x. In addition, the contact point of the second conductive bonding member 29B with the second portion 5B (the resistor 5) on the x1 side in the first direction x can be set based on the position of the end of the second pad portion 21B on the x1 side in the first direction x. As a result, the resistance value of the resistor 5 can be obtained properly, which makes it possible to accurately detect the current flowing through the conductive portion 2.

The first detection wiring 6A has a third extending portion 613. The third extending portion 613 is connected to the first extending portion 611, and extends to the y1 side in the second direction y. The second detection wiring 6B has a fourth extending portion 614. The fourth extending portion 614 is connected to the second extending portion 612, and extends to the y1 side in the second direction y. Such a configuration can prevent a short circuit between the first detection wiring 6A and the second detection wiring 6B, and can appropriately route these wirings 6A and 6B from under the resistor 5 to the surrounding area. In the present embodiment, the third extending portion 613 and the fourth extending portion 614 extend to the same side in the second direction y (the y1 side in the second direction y), but the third extending portion 613 and the fourth extending portion 614 may extend to the opposite side in the second direction y.

### First Variation of the First Embodiment

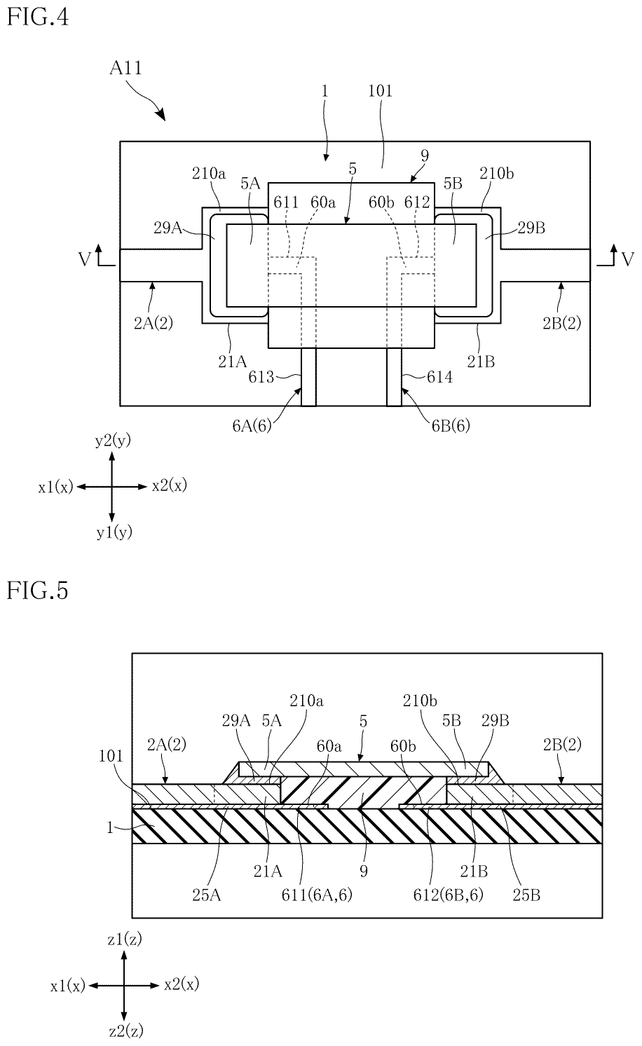

FIGS. 4 and 5 show a mounting structural body according to a first variation of the first embodiment. FIG. 4 is an enlarged plan view showing a part of a mounting structural body A11 of the present variation. FIG. 5 is a cross-sectional view taken along line V-V in FIG. 4. In FIG. 4 and the subsequent figures, the elements that are identical with or similar to those of the mounting structural body A1 in the above embodiment are designated by the same reference numerals as in the above embodiment, and the descriptions thereof are omitted as appropriate. The configurations of the elements in each variation and each embodiment shown in FIG. 4 and the subsequent figures can be combined as appropriate as long as the combination does not cause technical inconsistency.

The mounting structural body A11 of the present variation is additionally provided with an insulating film 9, as compared to the mounting structural body A1 of the above embodiment. The insulating film 9 is not particularly limited to a specific structure, and may be made of a resist layer or polyimide resin, for example.

The insulating film 9 is arranged in a predetermined area on the first obverse surface 101 and the detection wiring portion 6 (the first detection wiring 6A and the second detection wiring 6B). As shown in FIG. 5, the insulating film 9 is interposed between the first extending portion 611 (the first detection wiring 6A) and the resistor 5, and between the second extending portion 612 (the second detection wiring 6B) and the resistor 5. The insulating film 9 is in contact with the end of the first pad portion 21A on the x2 side in the first direction x, and with the end of the second pad portion 21B on the x1 side in the first direction x. The first conductive bonding member 29A and the second conductive bonding member 29B are in contact with the insulating film 9. The insulating film 9 having the configuration as described above is formed before the resistor 5 is disposed on the first pad portion 21A and the second pad portion 21B.

The mounting structural body A11 of the present variation can detect the current flowing through the conductive portion 2 by including the resistor 5. The circuit board on which the mounting structural body A11 is mounted does not need to include a separate resistor or route wires for a resistor, which makes it possible to save space. The mounting structural body A11 is additionally provided with an insulating film 9. The insulating film 9 is interposed between the first extending portion 611 (the first detection wiring 6A) and the resistor 5, and between the second extending portion 612 (the second detection wiring 6B) and the resistor 5. The first conductive bonding member 29A and the second conductive bonding member 29B are in contact with the insulating film 9. According to such a configuration, the contact point of the first conductive bonding member 29A with the first portion 5A (the resistor 5) on the x2 side in the first direction x and the contact point of the second conductive bonding member 29B with the second portion 5B (the resistor 5) on the x1 side in the first direction x can be set more accurately based on the position at which the insulating film 9 is formed. As a result, the resistance value of the resistor 5 can be obtained more properly, which makes it possible to more accurately detect the current flowing through the conductive portion 2. The mounting structural body A11 also has advantages similar to those of the mounting structural body A1 in the above embodiment.

### Second Variation of the First Embodiment

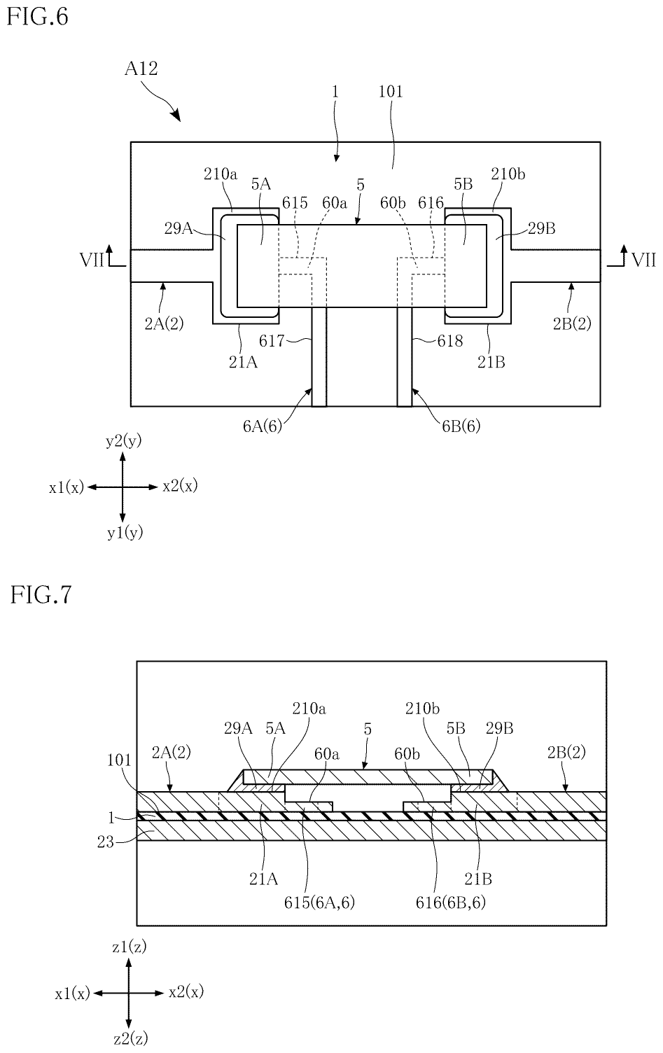

FIGS. 6 and 7 show a mounting structural body according to a second variation of the first embodiment. FIG. 6 is an enlarged plan view showing a part of a mounting structural body A12 of the present variation. FIG. 7 is a cross-sectional view taken along line VII-VII in FIG. 6. The mounting structural body A12 of the present variation is different from the mounting structural body A1 of the above embodiment in the configurations of the substrate 1, the conductive portion 2, and the detection wiring portion 6.

In the mounting structural body A12, the conductive portion 2 is directly bonded to the first obverse surface 101 of the substrate 1. Thus, unlike the mounting structural body A1 in the above embodiment, the mounting structural body A12 of the present variation does not include the first bonding layer 25A or the second bonding layer 25B. A reverse-surface metal layer 23 is bonded to the surface (the surface facing the z2 side in the thickness direction z) of the substrate 1 opposite to the first obverse surface 101. The conductive portion 2 is a metal layer formed on the obverse side (the first obverse surface 101) of the substrate 1, and the reverse-surface metal layer 23 is a metal layer formed on the reverse side (the surface opposite to the first obverse surface 101) of the substrate 1. The substrate 1 is a ceramic material having an excellent thermal conductivity, for example. Examples of such a ceramic material include silicon nitride (SiN) and alumina. The constituent material of each of the conductive portion 2 and the reverse-surface metal layer 23 contains Cu, for example. The constituent material may contain aluminum (Al) instead of Cu, for example. The substrate 1, the conductive portion 2, and the reverse-surface metal layer 23 having such configurations may be constituted by a direct bonded copper (DBC) substrate or an active metal brazing (AMB) substrate, for example.

In the mounting structural body A12, the conductive portion 2 is patterned to form a conductive path through which a current flows. In the present variation, the first conductive portion 2A has a first detection wiring 6A. As shown in FIG. 7, the first detection wiring 6A is connected to the first pad portion 21A, and has a thickness (dimension in the thickness direction z) smaller than that of the first pad portion 21A. The first wiring obverse surface 60a of the first detection wiring 6A is offset to the z2 side in the thickness direction z relative to the first pad obverse surface 210a of the first pad portion 21A. The second conductive portion 2B has a second detection wiring 6B. The second detection wiring 6B is connected to the second pad portion 21B, and has a thickness smaller that of the second pad portion 21B. The second wiring obverse surface 60b of the second detection wiring 6B is offset to the z2 side in the thickness direction z relative to the second pad obverse surface 210b of the second pad portion 21B. In the illustrated example, the thickness of the first detection wiring 6A (the second detection wiring 6B) is about half the thickness of the first pad portion 21A (the second pad portion 21B). The first detection wiring 6A and the second detection wiring 6B are formed by half-etching the conductive portion 2, for example.

The first detection wiring 6A has a fifth extending portion 615 and a seventh extending portion 617. As shown in FIGS. 6 and 7, the fifth extending portion 615 is connected to the first pad portion 21A, and extends from the first pad portion 21A to the x2 side in the first direction x as viewed in the thickness direction z. The fifth extending portion 615 overlaps with the resistor 5 as viewed in the thickness direction z. The seventh extending portion 617 is connected to the fifth extending portion 615, and extends to the y1 side in the second direction y. The seventh extending portion 617 has a portion overlapping with the resistor 5 and a portion not overlapping with the resistor 5, as viewed in the thickness direction z. This configuration allows the first detection wiring 6A (the fifth extending portion 615) to be electrically connected to the first pad portion 21A. The first detection wiring 6A is electrically connected to the first portion 5A of the resistor 5 via the first pad portion 21A and the first conductive bonding member 29A. The first detection wiring 6A (the seventh extending portion 617) is also electrically connected to the detection terminal 73 not shown in FIG. 6 or 7 (see FIG. 1).

The second detection wiring 6B has a sixth extending portion 616 and an eighth extending portion 618. As shown in FIGS. 6 and 7, the sixth extending portion 616 is connected to the second pad portion 21B, and extends from the second pad portion 21B to the x1 side in the first direction x as viewed in the thickness direction z. The sixth extending portion 616 overlaps with the resistor 5 as viewed in the thickness direction z. The eighth extending portion 618 is connected to the sixth extending portion 616, and extends to the y1 side in the second direction y. The eighth extending portion 618 has a portion overlapping with the resistor 5 and a portion not overlapping with the resistor 5, as viewed in the thickness direction z. This configuration allows the second detection wiring 6B (the sixth extending portion 616) to be electrically connected to the second pad portion 21B. The second detection wiring 6B is electrically connected to the second portion 5B of the resistor 5 via the second pad portion 21B and the second conductive bonding member 29B. The second detection wiring 6B (the eighth extending portion 618) is also electrically connected to the detection terminal 74 not shown in FIG. 6 or 7 (see FIG. 1).

The mounting structural body A12 of the present variation can detect the current flowing through the conductive portion 2 by including the resistor 5. The circuit board on which the mounting structural body A12 is mounted does not need to include a separate resistor or route wires for a resistor, which makes it possible to save space.

The conductive portion 2 includes a first conductive portion 2A and a second conductive portion 2B disposed on the first obverse surface 101 of the substrate 1. The first conductive portion 2A has a first pad portion 21A disposed on the x1 side in the first direction x, and the second conductive portion 2B has a second pad portion 21B offset from the first pad portion 21A to the x2 side in the first direction x. The resistor 5 has a first portion 5A overlapping with the first pad portion 21A as viewed in the thickness direction z, and a second portion 5B overlapping with the second pad portion 21B as viewed in the thickness direction z. A first conductive bonding member 29A is interposed between the first pad portion 21A (the first pad obverse surface 210a) and the first portion 5A. The first conductive bonding member 29A bonds the first pad portion 21A (the first pad obverse surface 210a) and the first portion 5A. A second conductive bonding member 29B is interposed between the second pad portion 21B (the second pad obverse surface 210b) and the second portion 5B. The second conductive bonding member 29B bonds the second pad portion 21B (the second pad obverse surface 210b) and the second portion 5B. With this configuration, the resistor 5 can be arranged appropriately on the path through which a current flows in the conductive portion 2.

The first conductive portion 2A has a first detection wiring 6A. The first detection wiring 6A has a fifth extending portion 615. The fifth extending portion 615 extends from the first pad portion 21A to the x2 side in the first direction x as viewed in the thickness direction z. The second conductive portion 2B has a second detection wiring 6B. The second detection wiring 6B has a sixth extending portion 616. The sixth extending portion 616 extends from the second pad portion 21B to the x1 side in the first direction x as viewed in the thickness direction z. According to the above configuration, a conductive path is formed that extends from the first portion 5A of the resistor 5 to the fifth extending portion 615 via the first conductive bonding member 29A and the first pad portion 21A. The first detection wiring 6A has a thickness (dimension in the thickness direction z) smaller than that of the first pad portion 21A. The first wiring obverse surface 60a of the first detection wiring 6A is offset to the z2 side in the thickness direction z relative to the first pad obverse surface 210a of the first pad portion 21A. With this configuration, there is a step in the thickness direction z between the end of the first pad portion 21A on the x2 side in the first direction x and the fifth extending portion 615 (the first detection wiring 6A), as shown in FIG. 7. This prevents the first conductive bonding member 29A made of solder from flowing inappropriately to the x2 side in the first direction x on the first pad portion 21A during the melting and bonding process. A conductive path is also formed on the side of the second portion 5B of the resistor 5. Specifically, the conductive path extends from the second portion 5B to the sixth extending portion 616 via the second conductive bonding member 29B and the second pad portion 21B. The second detection wiring 6B has a thickness smaller than that of the second pad portion 21B. The second wiring obverse surface 60b of the second detection wiring 6B is offset to the z2 side in the thickness direction z relative to the second pad obverse surface 210b of the second pad portion 21B. There is a step in the thickness direction z between the end of the second pad portion 21B on the x1 side in the first direction x and the sixth extending portion 616 (the second detection wiring 6B). This prevents the second conductive bonding member 29B made of solder from flowing inappropriately to the x1 side in the first direction x on the second pad portion 21B during the melting and bonding process. According to the configuration, the contact point of the first conductive bonding member 29A with the first portion 5A (the resistor 5) on the x2 side in the first direction x can be set based on the position of the end of the first pad portion 21A on the x2 side in the first direction x. In addition, the contact point of the second conductive bonding member 29B with the second portion 5B (the resistor 5) on the x1 side in the first direction x can be set based on the position of the end of the second pad portion 21B on the x1 side in the first direction X. As a result, the resistance value of the resistor 5 can be obtained properly, which makes it possible to accurately detect the current flowing through the conductive portion 2.

The first detection wiring 6A has a seventh extending portion 617. The seventh extending portion 617 is connected to the fifth extending portion 615, and extends to the y1 side in the second direction y. The second detection wiring 6B has an eighth extending portion 618. The eighth extending portion 618 is connected to the sixth extending portion 616, and extends to the y1 side in the second direction y. Such a configuration can prevent a short circuit between the first detection wiring 6A and the second detection wiring 6B, and can appropriately route these wirings 6A and 6B from under the resistor 5 to the surrounding area. In the present variation, the seventh extending portion 617 and the eighth extending portion 618 extend to the same side in the second direction y (the y1 side in the second direction y), but the seventh extending portion 617 and the eighth extending portion 618 may extend to the opposite side in the second direction y.

### Third Variation of the First Embodiment

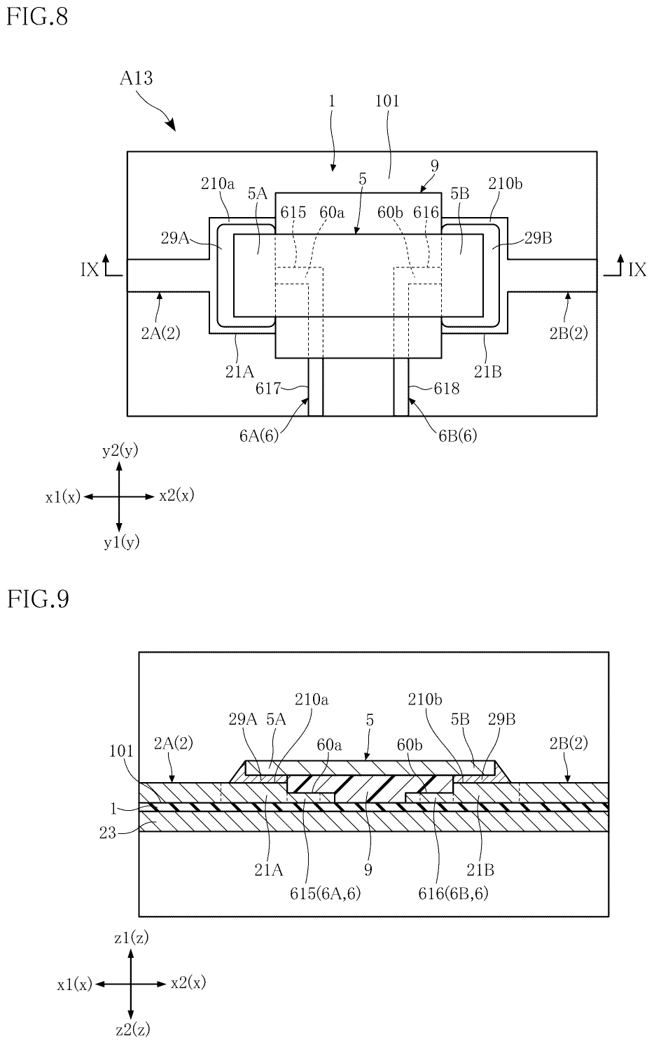

FIGS. 8 and 9 show a mounting structural body according to a third variation of the first embodiment. FIG. 8 is an enlarged plan view showing a part of a mounting structural body A13 of the present variation. FIG. 9 is a cross-sectional view taken along line IX-IX in FIG. 8. The mounting structural body A13 of the present variation is additionally provided with an insulating film 9, as compared to the mounting structural body A12 of the second variation described above. The insulating film 9 is not particularly limited to a specific structure, and may be made of a resist layer or polyimide resin, for example.

The insulating film 9 is arranged in a predetermined area on the first obverse surface 101 and the detection wiring portion 6 (the first detection wiring 6A and the second detection wiring 6B). As shown in FIG. 9, the insulating film 9 is interposed between the fifth extending portion 615 (the first detection wiring 6A) and the resistor 5, and between the sixth extending portion 616 (the second detection wiring 6B) and the resistor 5. The insulating film 9 is in contact with the end of the first pad portion 21A on the x2 side in the first direction x, and with the end of the second pad portion 21B on the x1 side in the first direction x. The first conductive bonding member 29A and the second conductive bonding member 29B are in contact with the insulating film 9. The insulating film 9 having the configuration as described above is formed before the resistor 5 is disposed on the first pad portion 21A and the second pad portion 21B.

The mounting structural body A13 of the present variation can detect the current flowing through the conductive portion 2 by including the resistor 5. The circuit board on which the mounting structural body A13 is mounted does not need to include a separate resistor or route wires for a resistor, which makes it possible to save space. The mounting structural body A13 is additionally provided with an insulating film 9. The insulating film 9 is interposed between the fifth extending portion 615 (the first detection wiring 6A) and the resistor 5, and between the sixth extending portion 616 (the second detection wiring 6B) and the resistor 5. The first conductive bonding member 29A and the second conductive bonding member 29B are in contact with the insulating film 9. According to such a configuration, the contact point of the first conductive bonding member 29A with the first portion 5A (the resistor 5) on the x2 side in the first direction x and the contact point of the second conductive bonding member 29B with the second portion 5B (the resistor 5) on the x1 side in the first direction x can be set more accurately based on the position at which the insulating film 9 is formed. As a result, the resistance value of the resistor 5 can be obtained more properly, which makes it possible to more accurately detect the current flowing through the conductive portion 2. The mounting structural body A13 also has advantages similar to those of the mounting structural body A12 in the variation described above.

The mounting structural body (the mounting structure for a resistor) according to the present disclosure is not limited to that in the above embodiment. Various design changes can be made to the specific configurations of the elements of the mounting structure for a resistor according to the present disclosure.

In the above embodiment, the resistor 5 has two terminals corresponding to the first portion 5A and the second portion 5B, but may have four terminals including two additional terminals for detection. The resistor 5 can be modified appropriately regardless of the number of terminals. If the resistor 5 has four terminals, the configurations of the first pad portion 21A, the second pad portion 21B, and the detection wiring portion 6 (the first detection wiring 6A and the second detection wiring 6B) can be modified appropriately to suit the configuration of the resistor 5.

The present disclosure includes the configurations relating to the following clauses.

Clause 1:

A resistor mounting structure comprising:
a substrate;
a conductive portion supported by the substrate;
a resistor arranged on a path through which a current flows in the conductive portion; and
a detection wiring portion electrically connected to the resistor,
wherein the substrate includes a first obverse surface facing a first side in a thickness direction,
the conductive portion includes a first conductive portion and a second conductive portion each arranged on the first obverse surface,
the first conductive portion includes a first pad portion arranged on a first side in a first direction perpendicular to the thickness direction,
the second conductive portion includes a second pad portion offset from the first pad portion to a second side in the first direction,
the resistor includes a first portion overlapping with the first pad portion as viewed in the thickness direction, and a second portion overlapping with the second pad portion as viewed in the thickness direction,
the first pad portion includes a first pad obverse surface facing the first side in the thickness direction,
the second pad portion includes a second pad obverse surface facing the first side in the thickness direction,
the resistor mounting structure further includes a first conductive bonding member interposed between the first pad obverse surface and the first portion to bond the first pad obverse surface and the first portion, and a second conductive bonding member interposed between the second pad obverse surface and the second portion to bond the second pad obverse surface and the second portion,
the detection wiring portion includes a first detection wiring electrically connected to the first pad portion, and a second detection wiring electrically connected to the second pad portion,
the first detection wiring includes a first wiring obverse surface facing the first side in the thickness direction,
the second detection wiring includes a second wiring obverse surface facing the first side in the thickness direction,
the first wiring obverse surface is offset to a second side in the thickness direction relative to the first pad obverse surface, and
the second wiring obverse surface is offset to the second side in the thickness direction relative to the second pad obverse surface.

Clause 2:

The resistor mounting structure according to clause 1, further comprising a first bonding layer interposed between the first obverse surface and the first pad portion to bond the first obverse surface and the first pad portion, and a second bonding layer interposed between the first obverse surface and the second pad portion to bond the first obverse surface and the second pad portion.

Clause 3:

The resistor mounting structure according to clause 2, wherein the first bonding layer and the second bonding layer are electrically conductive,
the first bonding layer includes the first detection wiring, and
the second bonding layer includes the second detection wiring.

Clause 4:

The resistor mounting structure according to clause 3, wherein the first detection wiring includes a first extending portion extending from the first pad portion to the second side in the first direction as viewed in the thickness direction, and
the second detection wiring includes a second extending portion extending from the second pad portion to the first side in the first direction as viewed in the thickness direction.

Clause 5:

The resistor mounting structure according to clause 4, wherein the first detection wiring includes a third extending portion connected to the first extending portion and extending in a second direction perpendicular to the thickness direction and the first direction, and
the second detection wiring includes a fourth extending portion connected to the second extending portion and extending in the second direction.

Clause 6:

The resistor mounting structure according to any of clauses 2 to 5, wherein the substrate is made of a ceramic material.

Clause 7:

The resistor mounting structure according to clause 1, wherein the first conductive portion includes the first detection wiring,
the second conductive portion includes the second detection wiring,
the first detection wiring is connected to the first pad portion and thinner than the first pad portion, and
the second detection wiring is connected to the second pad portion and thinner than the second pad portion.

Clause 8:

The resistor mounting structure according to clause 7, wherein the first detection wiring has a fifth extending portion connected to the first pad portion and extending from the first pad portion to the second side in the first direction, and
the second detection wiring has a sixth extending portion connected to the second pad portion and extending from the second pad portion to the first side in the first direction.

Clause 9:

The resistor mounting structure according to clause 8, wherein the first detection wiring includes a seventh extending portion connected to the fifth extending portion and extending in a second direction perpendicular to the thickness direction and the first direction, and
the second detection wiring includes an eighth extending portion connected to the sixth extending portion and extending in the second direction.

Clause 10:

The resistor mounting structure according to any of clauses 7 to 9, further comprising a reverse-surface metal layer bonded to a surface of the substrate facing an opposite side from the first obverse surface,
wherein the substrate is made of a ceramic material.

Clause 11:

The resistor mounting structure according to any of clauses 1 to 10, further comprising an insulating film interposed between the first detection wiring and the resistor and also between the second detection wiring and the resistor,
wherein the first conductive bonding member and the second conductive bonding member are in contact with the insulating film.

Clause 12:

The resistor mounting structure according to any of clauses 1 to 11, wherein the first conductive bonding member and the second conductive bonding member are made of solder.

### REFERENCE NUMERALS

A1, A11, A12, A13: Mounting structural body
1: Substrate 2: Conductive portion
2A: First conductive portion 2B: Second conductive portion
21A: First pad portion 21B: Second pad portion
210a: First pad obverse surface 210b: Second pad obverse surface
23: Reverse-surface metal layer 25A: First bonding layer 25B: Second bonding layer 29A: First conductive bonding member
29B: Second conductive bonding member 5: Resistor
5A: First portion 5B: Second portion
6: Detection wiring portion 6A: First detection wiring 6B: Second detection wiring 60a: First wiring obverse surface
60b: Second wiring obverse surface 611: First extending portion
612: Second extending portion 613: Third extending portion 614: Fourth extending portion 615: Fifth extending portion 616: Sixth extending portion 617: Seventh extending portion 618: Eighth extending portion 71, 72: Terminal
73, 74: Detection terminal 8: Sealing resin
9: Insulating film

1. A resistor mounting structure comprising:
a substrate;
a conductive portion supported by the substrate;
a resistor arranged on a path through which a current flows in the conductive portion; and
a detection wiring portion electrically connected to the resistor,
wherein the substrate includes a first obverse surface facing a first side in a thickness direction,
the conductive portion includes a first conductive portion and a second conductive portion each arranged on the first obverse surface,
the first conductive portion includes a first pad portion arranged on a first side in a first direction perpendicular to the thickness direction,
the second conductive portion includes a second pad portion offset from the first pad portion to a second side in the first direction,
the resistor includes a first portion overlapping with the first pad portion as viewed in the thickness direction, and a second portion overlapping with the second pad portion as viewed in the thickness direction,
the first pad portion includes a first pad obverse surface facing the first side in the thickness direction,
the second pad portion includes a second pad obverse surface facing the first side in the thickness direction,
the resistor mounting structure further includes a first conductive bonding member interposed between the first pad obverse surface and the first portion to bond the first pad obverse surface and the first portion, and a second conductive bonding member interposed between the second pad obverse surface and the second portion to bond the second pad obverse surface and the second portion,
the detection wiring portion includes a first detection wiring electrically connected to the first pad portion, and a second detection wiring electrically connected to the second pad portion,
the first detection wiring includes a first wiring obverse surface facing the first side in the thickness direction,
the second detection wiring includes a second wiring obverse surface facing the first side in the thickness direction,
the first wiring obverse surface is offset to a second side in the thickness direction relative to the first pad obverse surface, and
the second wiring obverse surface is offset to the second side in the thickness direction relative to the second pad obverse surface.

2. The resistor mounting structure according to claim 1, further comprising a first bonding layer interposed between the first obverse surface and the first pad portion to bond the first obverse surface and the first pad portion, and a second bonding layer interposed between the first obverse surface and the second pad portion to bond the first obverse surface and the second pad portion.

3. The resistor mounting structure according to claim 2, wherein the first bonding layer and the second bonding layer are electrically conductive,
the first bonding layer includes the first detection wiring, and
the second bonding layer includes the second detection wiring.

4. The resistor mounting structure according to claim 3, wherein the first detection wiring includes a first extending portion extending from the first pad portion to the second side in the first direction as viewed in the thickness direction, and
the second detection wiring includes a second extending portion extending from the second pad portion to the first side in the first direction as viewed in the thickness direction.

5. The resistor mounting structure according to claim 4, wherein the first detection wiring includes a third extending portion connected to the first extending portion and extending in a second direction perpendicular to the thickness direction and the first direction, and
the second detection wiring includes a fourth extending portion connected to the second extending portion and extending in the second direction.

6. The resistor mounting structure according to claim 2, wherein the substrate is made of a ceramic material.

7. The resistor mounting structure according to claim 1, wherein the first conductive portion includes the first detection wiring,
the second conductive portion includes the second detection wiring,
the first detection wiring is connected to the first pad portion and thinner than the first pad portion, and
the second detection wiring is connected to the second pad portion and thinner than the second pad portion.

8. The resistor mounting structure according to claim 7, wherein the first detection wiring has a fifth extending portion connected to the first pad portion and extending from the first pad portion to the second side in the first direction, and
the second detection wiring has a sixth extending portion connected to the second pad portion and extending from the second pad portion to the first side in the first direction.

9. The resistor mounting structure according to claim 8, wherein the first detection wiring includes a seventh extending portion connected to the fifth extending portion and extending in a second direction perpendicular to the thickness direction and the first direction, and
the second detection wiring includes an eighth extending portion connected to the sixth extending portion and extending in the second direction.

10. The resistor mounting structure according to claim 7, further comprising a reverse-surface metal layer bonded to a surface of the substrate facing an opposite side from the first obverse surface,
wherein the substrate is made of a ceramic material.

11. The resistor mounting structure according to claim 1, further comprising an insulating film interposed between the first detection wiring and the resistor and also between the second detection wiring and the resistor,
wherein the first conductive bonding member and the second conductive bonding member are in contact with the insulating film.

12. The resistor mounting structure according to claim 1, wherein the first conductive bonding member and the second conductive bonding member are made of solder.
